(19) United States
(12) Patent Application Publication
(10) Pub. No.: US 2025/0054761 A1
(43) Pub. Date: Feb. 13, 2025

(54) SEMICONDUCTOR DEVICE AND METHOD FOR MANUFACTURING SAME

(71) Applicant: Microchip Technology Incorporated, Chandler, AZ (US)

(72) Inventors: Shesh Mani Pandey, Gilbert, AZ (US); Bruce Odekirk, Portland, OR (US)

(73) Assignee: Microchip Technology Incorporated, Chandler, AZ (US)

(21) Appl. No.: 18/676,191

(22) Filed: May 28, 2024

Related U.S. Application Data
(60) Provisional application No. 63/531,880, filed on Aug. 10, 2023.

(51) Int. Cl. H01L 21/04; H01L 29/16; H01L 29/51

(52) U.S. Cl. CPC H01L 21/049; H01L 29/1608; H01L 29/51

(57) ABSTRACT

A semiconductor device that may include a silicon carbide substrate, a silicon layer disposed on the silicon carbide substrate, and a gate oxide layer disposed on the silicon layer. The silicon layer may be implanted within the silicon carbide substrate. The silicon layer may comprise a thickness of 100 angstroms 5000 angstroms. The silicon layer may contain less than one percent carbon, or may contain a certain percentage of carbon that decreases as a distance from the surface of the silicon carbide substrate increases.

### CROSS-REFERENCE TO RELATED APPLICATION

The present application claims priority to U.S. Provisional Patent Application No. 63/531,880, filed on Aug. 10, 2023, the contents of which are hereby incorporated by reference in their entirety.

### TECHNICAL FIELD

The present disclosure relates generally to semiconductor substrates for electronic devices, and more specifically to silicon carbide substrates and a gate oxide layer with the silicon carbide substrate.

### SUMMARY

According to an aspect of one or more examples, there is provided a method of fabricating a semiconductor device. The method may include forming a silicon layer on a surface of a silicon carbide substrate, and forming a gate oxide layer over the silicon layer. The silicon layer may comprise a thickness of 100 angstroms to 5000 angstroms. The silicon layer may contain less than one percent carbon, or may contain a certain percentage of carbon that decreases as a distance from the surface of the silicon carbide substrate increases. The step of forming the gate oxide layer may include oxidizing silicon from the silicon layer to form the gate oxide layer of silicon dioxide.

According to another aspect of one or more examples, there is provided a method of fabricating a semiconductor device. The method may include implanting silicon into a silicon carbide substrate to form a first silicon rich layer, forming a second silicon layer over the first silicon layer using epitaxial growth, and forming a gate oxide layer on the second silicon layer. Silicon rich means that the percent of silicon is greater than the percent of carbon, e.g., the silicon percentage could be twenty-five percent higher than the carbon percentage. In some example, a higher percentage of silicon may be better than a lower percentage of silicon, for example the higher percentage of silicon may reduce the number of defects. The first silicon layer and the second silicon layer may together comprise a thickness of 100 angstroms to 5000 angstroms. The second silicon layer may contain less than one percent carbon, or may contain a certain percentage of carbon that decreases as a distance from the surface of the silicon carbide substrate increases. The step of forming the gate oxide layer may include oxidizing silicon from the second silicon layer to form the gate oxide layer of silicon dioxide.

According to another aspect of one or more examples, there is provided a method of fabricating a semiconductor device. The method may include forming a first silicon layer on a surface of the silicon carbide substrate, polishing the first silicon layer, forming a second silicon layer over the first silicon layer, and forming a gate oxide layer over the second silicon layer. The first silicon layer and the second silicon layer together may comprise a thickness of 100 angstroms to 5000 angstroms. The second silicon layer may contain less than one percent carbon, or may contain a certain percentage of carbon that decreases as a distance from the surface of the silicon carbide substrate increases. The step of forming the gate oxide layer may include oxidizing silicon from the second silicon layer to form the gate oxide layer of silicon dioxide.

According to another aspect of one or more examples, there is provided a semiconductor device that may include a silicon carbide substrate, a silicon layer disposed on the silicon carbide substrate, and a gate oxide layer disposed on the silicon layer. The silicon layer may be implanted within the silicon carbide substrate. The silicon layer may comprise a thickness of 100 angstroms to 5000 angstroms. The silicon layer may contain less than one percent carbon, or may contain a certain percentage of carbon that decreases as a distance from the surface of the silicon carbide substrate increases.

### BRIEF DESCRIPTION OF DRAWINGS

FIGS. 1A-1C show a silicon carbide substrate with a layer of silicon grown or deposited and an oxide layer and a method of manufacturing the semiconductor device according to one or more examples.

FIG. 2 shows a graph demonstrating potential carbon concentration in the silicon layer of the semiconductor device thereof according to one or more examples.

FIGS. 3A-3C show a silicon carbide substrate with a first silicon rich layer implanted, a second layer of silicon grown or deposited thereon, and an oxide layer formed on the second layer of silicon, and a method of manufacturing the semiconductor device according to one or more examples.

FIGS. 4A-4D show a silicon carbide substrate with a layer of silicon grown or deposited, then polished, with additional silicon grown or deposited on the polished silicon, and an oxide layer formed thereon, and a method of manufacturing the semiconductor device according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

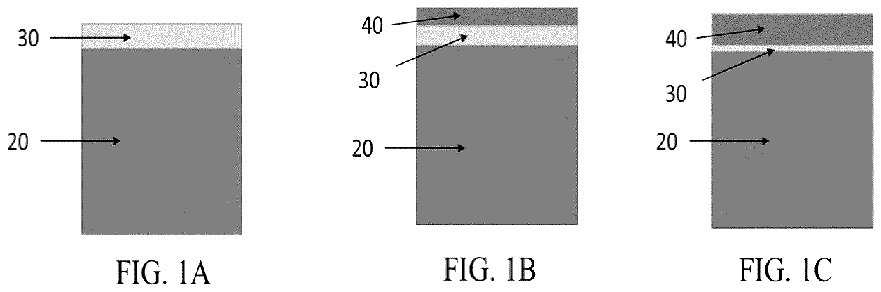

FIGS. 1A-1C shows a silicon carbide substrate and a method of manufacturing the silicon carbide substrate according to one or more examples. Silicon carbide is often used as a substrate to create many semiconductor devices, and may result in reduced switching losses, higher power density, improved heat dissipation, and increased bandwidth as compared with other materials. Some semiconductor devices, such as metal-oxide-semiconductor field-effect transistors (MOSFETs) include a gate oxide layer that is a dielectric layer that separates the silicon carbide substrate from a gate electrode, which may be made of metal or other conductive material.

When forming the gate oxide layer on a silicon carbide substrate, the interface between the silicon carbide substrate and the gate oxide layer (for example, a gate oxide layer made of silicon dioxide) may be very rough. The rough interface between the gate oxide layer and the silicon carbide substrate may degrade carrier mobility in the silicon carbide substrate, which may limit device performance. In order to at least partially resolve this difficulty, and referring to FIG. 1A, a layer of silicon (Si) 30 may be grown or deposited on a surface of a silicon carbide (SiC) substrate 20. According to one or more examples, the silicon layer 30 may be approximately 100 angstroms to 5000 angstroms thick, though other thicknesses may be used depending on the application. For example, the amount of silicon used to create the silicon layer 30 may depend on the thickness of the gate oxide layer to be formed on the silicon layer 30. As shown in FIG. 1B, a gate oxide layer 40 may be formed on the silicon layer 30. For example, the gate oxide layer 40 may be a layer of silicon dioxide, which may be formed or grown by a thermal oxidation process of the silicon layer 30. According to an example shown in FIG. 1C, a very thin layer of silicon 30, or no silicon, may remain between the silicon carbide substrate 20 and the gate oxide layer 40, when gate oxide layer 40 is comprised of silicon dioxide.

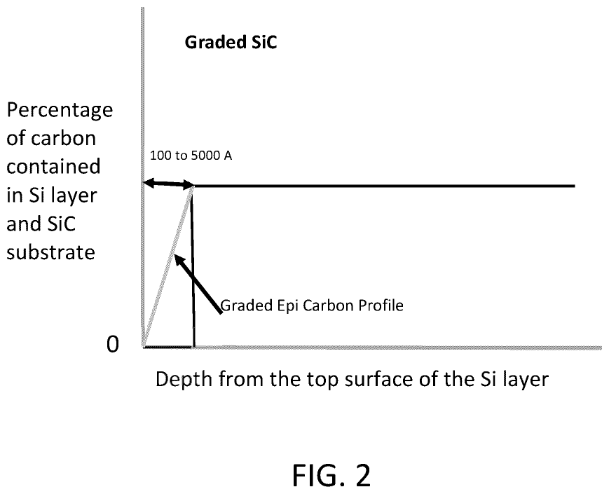

FIG. 2 shows a graph demonstrating potential carbon concentration of silicon layer 30 according to one or more examples. As shown in the graph in FIG. 2, the vertical axis indicates the percentage of carbon contained in silicon layer 30 and silicon carbide substrate 20, and the horizontal access indicates the depth from the top surface of the silicon layer 30. Thus, the silicon layer 30 presents a graded silicon carbide layer, as the percentage of carbon in the silicon layer 30 decreases as a distance from the surface of the silicon carbide substrate increases. At the point where the silicon layer interfaces with the silicon carbide substrate, the percentage carbon increases to indicate a fixed carbon percentage in the silicon carbide substrate. According to an example demonstrated by the graph of FIG. 2, the carbon percentage in the silicon layer may be approximately zero at the top of the silicon layer 30, and may increase as the distance from the silicon carbide substrate decreases, i.e. as the distance from the top of the silicon layer 30 increases. As shown in the example in FIG. 2, the percentage of carbon in the silicon layer may increase approximately linearly until reaching the silicon carbide substrate, at which point the carbon percentage may become constant. Alternatively, the percentage of carbon may increase non-linearly in the silicon layer.

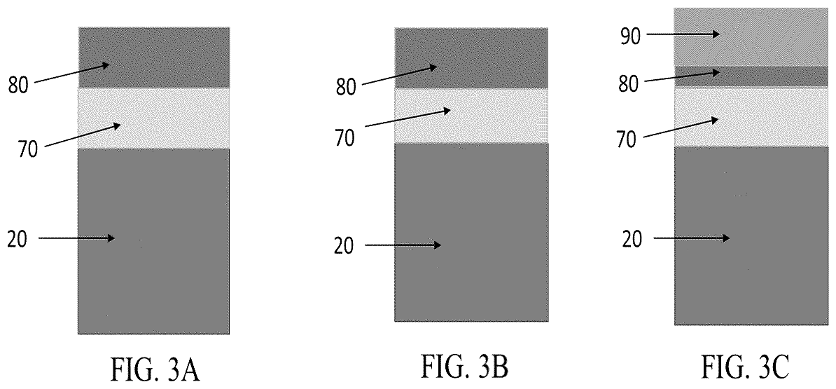

A method of manufacturing a silicon layer on a silicon carbide substrate is herein enabled according to one or more examples. FIGS. 3A-3C show a silicon carbide substrate and a method of manufacturing the silicon carbide substrate according to one or more examples. In FIG. 3A, a first silicon rich layer 70 may be implanted within an upper portion of a silicon carbide substrate 20. Silicon rich means that the percent of silicon is greater than the percent of carbon, e.g., the silicon percentage could be twenty-five percent higher than the carbon percentage, without limitation. According to an example, the implanted depth of the implanted first silicon rich layer 70 may be approximately 100 angstroms to 5000 angstroms thick, though other thicknesses may be used. First silicon rich layer 70 may be formed by implanting silicon into the silicon carbide substrate 20. As shown in FIG. 3B, after the first silicon rich layer 70 is implanted within the upper portion of the silicon carbide substrate 20, a second silicon layer 80 may be formed by using epitaxial growth on the implanted first silicon rich layer 70. By implanting the first silicon rich layer 70, there is a sufficient amount of silicon on top of the silicon carbide substrate 20 to obtain a better quality second silicon layer 80, i.e. the silicon layer 80 may have fewer defects than may happen in the absence of the first silicon rich layer 70. For example, the second silicon layer 80 may be a single crystalline layer. As shown in FIG. 3C, after the second silicon layer 80 is formed, a gate oxide layer 90 may be formed on the second silicon layer 80. For example, the gate oxide layer 90 may be a layer of silicon dioxide, which may be formed or grown by a thermal oxidation process of the second silicon layer 80. Once the gate oxide layer 90 is formed, a portion of the second silicon layer 80 may remain between the implanted first silicon rich layer 70 and the gate oxide layer 90, or there may be no portion of the second silicon layer 80 remaining after the gate oxide layer 90 is formed. The second silicon layer 80 may include less than one percent carbon, or alternatively the carbon percentage in the second silicon layer 80 may be approximately zero at the top of the second silicon layer 80, and the carbon percentage may increase as the distance from the silicon carbide substrate 20 decreases. In other words, the percentage of carbon in the second silicon layer 80 may decrease as a distance from the silicon carbide substrate 20 increases. This can be accomplished during epitaxial growth, for example, by gradually reducing the percentage of carbon incorporation.

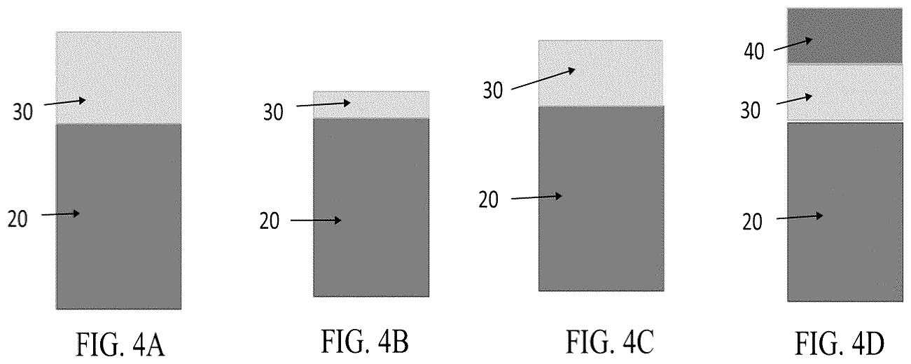

A method of manufacturing a silicon carbide substrate is herein enabled according to one or more examples. FIGS. 4A-4D show a silicon carbide substrate and a method of manufacturing the silicon carbide substrate according to one or more examples. In FIG. 4A, a layer of silicon 30 may be grown or deposited on a surface of a silicon carbide substrate 20. When the silicon layer 30 is grown, the silicon layer 30 may have different types of defects. The silicon layer 30 may be polished to remove a portion of the silicon layer as shown in FIG. 4B, which polishing may remove portions of the silicon layer 30 containing some of the defects. After the silicon layer 30 is polished, additional silicon may be grown or deposited on the existing silicon layer 30 as shown in FIG. 4C. The silicon layer 30 may then be polished again to remove a portion of the silicon layer 30 that may contain defects. This process of growing or depositing silicon and polishing the silicon layer 30 may be repeated until a silicon layer 30 of sufficient quality is obtained. For example, the process may be repeated until a single crystalline silicon layer 30 is obtained. In one example, the additional silicon may contain less than one percent carbon. In one example, a percentage of carbon in the additional silicon decreases as a distance from the surface of the silicon carbide substrate increases. Once a sufficient silicon layer 30 is obtained, a gate oxide layer 40 may be formed on the silicon layer 30 as shown in FIG. 4D. For example, the gate oxide layer 40 may be a layer of silicon dioxide, which may be formed or grown by a thermal oxidation process of the silicon layer 30. According to an example, when the gate oxide layer 40 is formed, a layer of silicon 30 may remain between the silicon carbide substrate 20 and the gate oxide layer 40. According to an example, a very thin layer of silicon, or no silicon, may remain between the silicon carbide substrate 20 and the gate oxide layer 40.

Various examples have been disclosed herein, in connection with the above description and the drawings. It will be understood that it would be unduly repetitious to literally describe and illustrate every combination and sub-combination of these examples. Accordingly, all examples may be combined in any way and/or combination, and the present specification, including the drawings, shall be construed to constitute a complete written description of all combinations and sub-combinations of the examples described herein, and of the manner and process of making and using them, and shall support claims to any such combination or sub-combination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A method of fabricating a semiconductor device, the method comprising:
forming a silicon layer on a surface of a silicon carbide substrate; and
forming a gate oxide layer over the silicon layer.

2. The method of claim 1, wherein the silicon layer comprises a thickness of 100 angstroms to 5000 angstroms.

3. The method of claim 1, wherein the silicon layer contains less than one percent carbon.

4. The method of claim 1, wherein a percentage of carbon in the silicon layer decreases as a distance from the surface of the silicon carbide substrate increases towards the top of the silicon layer.

5. The method of claim 1, wherein the step of forming the gate oxide layer includes oxidizing silicon from the silicon layer, such that the gate oxide layer is comprised of silicon dioxide.

6. A method of fabricating a semiconductor device, the method comprising:
implanting silicon into a silicon carbide substrate to form a first silicon rich layer;
forming a second silicon layer over the first silicon rich layer using epitaxial growth; and
forming a gate oxide layer over the second silicon layer.

7. The method of claim 6, wherein the second silicon layer contains less than one percent carbon.

8. The method of claim 6, wherein a percentage of carbon in the second silicon layer decreases as a distance from the silicon carbide substrate increases.

9. The method of claim 6, wherein the step of forming the gate oxide layer includes oxidizing silicon from the second silicon layer to form the gate oxide layer such that the gate oxide layer is comprised of silicon dioxide.

10. A method of fabricating a semiconductor device, the method comprising:
forming a silicon layer on a surface of a silicon carbide substrate;
polishing the silicon layer;
forming additional silicon over the polished silicon layer; and
forming a gate oxide layer over the additional silicon.

11. The method of claim 10, wherein the polished silicon layer and the additional silicon comprises a combined thickness of 100 angstroms to 5000 angstroms.

12. The method of claim 10, wherein the additional silicon contains less than one percent carbon.

13. The method of claim 10, wherein a percentage of carbon in the additional silicon decreases as a distance from the surface of the silicon carbide substrate increases.

14. The method of claim 10, wherein the step of forming the gate oxide layer includes oxidizing silicon from the additional silicon to form the gate oxide layer such that the gate oxide layer is comprised of silicon dioxide.

15. A semiconductor device comprising:
a silicon carbide substrate;
a silicon layer on a surface of the silicon carbide substrate; and
a gate oxide layer over the silicon layer.

16. The semiconductor device of claim 15, wherein the silicon layer comprises a thickness of 100 angstroms to 5000 angstroms.

17. The semiconductor device of claim 15, wherein the silicon layer is implanted into the silicon carbide substrate.

18. The semiconductor device of claim 15, wherein the silicon layer contains less than one percent carbon.

19. The semiconductor device of claim 15, wherein a percentage of carbon in the silicon layer decreases as a distance from the silicon carbide substrate increases.
